(19) United States
(12) Patent Application Publication
(10) Pub. No.: US 2024/0355759 A1
(43) Pub. Date: Oct. 24, 2024

(54) LOCALIZED DAMPING ELEMENTS FOR MITIGATING INTERCONNECT VIBRATION DAMAGE

(71) Applicant: Intel Corporation, Santa Clara, CA (US)

(72) Inventors: Phil Geng, Washougal, WA (US); Baris Bicen, Chandler, AZ (US); Kai Xiao, Portland, OR (US); Sanjoy Saha, Portland, OR (US); Prasanna Raghavan, Chandler, AZ (US)

(73) Assignee: Intel Corporation, Santa Clara, CA (US)

(21) Appl. No.: 18/136,775

(22) Filed: Apr. 19, 2023

(51) Int. Cl. H01L 23/00

(52) U.S. Cl. CPC H01L 23/562; H01L 23/3675; H01L 23/4006; H01L 2023/4081; H01L 2023/4087; H01L 23/427; H01L 24/32; H01L 24/71; H01L 2224/32245; H01L 2224/71

(57) ABSTRACT

Damping structures in integrated circuit (IC) devices, and techniques for forming the structures are discussed. An IC device includes, between an IC package and a socket, both a spring force and a damping structure adjacent an array of pins and corresponding lands. The damping structure may be of a dissipative, viscous, or viscoelastic material. The damping structure may be between the IC package and socket. The damping structure may be within a periphery of the socket. The damping structure may be coupled to the IC package or the socket by an adhesive or a press fit. A heatsink or a heat spreader may be coupled to the IC package over the socket.

### BACKGROUND

As integrated circuit (IC) devices grow increasingly complex, IC packages and corresponding sockets have correspondingly more pins and contacts for interfacing with each other. The risk of damage to pins or contacts also increases, particularly as loading forces grow to match the escalating quantity of pins. Vibration damage, including scratching or fretting of land pads under these compressive forces, may degrade performance and reliability of IC devices. For example, fretting may deteriorate contact and cause delamination, either of which may reduce performance during standard conditions or qualification testing. Improved structures and methods are needed to manage vibration concerns.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIGS. 1A and 1B illustrate cross-sectional profile and isometric views of damping structures between an integrated circuit (IC) package and a socket in an IC device, in accordance with some embodiments;

FIG. 2 illustrates a cross-sectional profile view of damping structures between an IC package and a socket in an IC device, in accordance with some embodiments;

FIGS. 3A and 3B illustrates a cross-sectional profile view of damping structures between an IC package and a socket in an IC device, in accordance with some embodiments;

FIG. 4 illustrates a cross-sectional profile view of damping structures between an IC package and a socket in an IC device, in accordance with some embodiments;

FIG. 5 illustrates a cross-sectional profile view of a damping structure between an IC package and a socket in an IC device, in accordance with some embodiments;

FIGS. 6A, 6B, and 6C illustrate cross-sectional profile and isometric views of a damping structure between an IC package and a socket in an IC device, in accordance with some embodiments;

FIG. 7 illustrates a plan view of damping structures between an IC package and a socket in an IC device, in accordance with some embodiments;

FIG. 8 is a flow chart of methods for forming an IC device with an IC package, a socket, and a damping structure between the package and socket, in accordance with some embodiments;

FIG. 9 illustrates a diagram of an example data server machine employing an IC package in a socket with a damping structure between the package and socket, in accordance with some embodiments; and

FIG. 10 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Materials, structures, and techniques are disclosed to improve the performance of integrated circuit (IC) devices with packages and sockets coupled by pins and lands. Such pins may be compression springs that are shortened as the pins are loaded when an IC package and socket are coupled. For example, hundreds or thousands of pins may be in an array on the socket, each a cantilever spring contacting a corresponding pad on the IC package, e.g., in a grid or array of contacts on a land grid array (LGA) package. These pins may produce vibration fretting, including more severe fretting on lands at certain corners or edges, or for different vendors or socket designs. Fretting on lands, besides scratching, may result in corrosion at scratches and increased contact resistance, and/or additional material (including of expensive materials, such as gold) may be used to mitigate against fretting.

This disclosure describes damping structures between sockets and IC packages to mitigate vibration damage at high-risk locations or features. Vibration fretting may be driven by one or more of various causes, including thermal solutions and mechanical retention, and may require one or more solutions adaptable to a variety of issues. For example, thermal solutions may include heavy heatsinks and may cause significant displacement of a heatsink module relative to the socket during vibration. Mechanical retention of IC packages may include springs applying a force between an IC package and socket, e.g., to meet socket load requirements or to fix a heatsink to socket stack. Such loading springs (or a heavy heatsink, etc.) may interact with the array of pin springs to generate one or more modes of oscillations, for example, side-to-side, up-and-down, or a combination (such as a rocking mode pivoting about an axis). Such gravitational and spring forces may interact with the socket and package during normal operation, shipping, reliability testing, etc., to cause fretting or other problems. Although much of this disclosure may describe LGA packages, LGA sockets (with flexible pins for contacting the LGA), and associated problems (e.g., fretting), vibrations between other types of sockets and IC packages may be problematic as well. For example, pin grid array (PGA) packages have rigid pins that may mate with holes in a PGA socket. Vibration of rigid pins relative to pin holes or contacts may also cause mechanical damage, for example, to pins. Various packages and sockets may benefit from reduced vibrations.

A damping structure may be introduced between a socket and IC package, e.g., wherever vibration fretting is significant, to reduce or prevent oscillations between the two. For example, damping structures may be installed within a socket or on an IC package wherever fretting is observed or expected, such as on a seating plane of a socket near the edges or corners of an array of pins. The damping structures need not support significant load under static conditions and need not affect socket loading design. Under vibration load, the localized damping structures may take dynamic load from the pins and reduce pin fretting. By adding damping structures at high pin fretting locations, the design may effectively mitigate local pin fretting risk, improve the performance of a particular socket design, or increase vibration reliability margin. Localized damping structures may reduce costs, for example, relative to a solution implemented for an entire socket system or before encountering a particular vibration problem.

Damping structures may be rectangular, circular, or other shapes to fit an available space. The damping structure can be made of a dissipative material, such as cork, felt, rubber, etc. The dissipative material may be a viscoelastic material, such as an elastomer, which may be more viscous or less elastic than a spring material. One or more damping structures may be placed within a periphery or footprint of the socket on either or both of the IC package and socket. A damping structure may contact either of the package or socket, or the damping structure may span between and contact both of the package and socket. A damping structure may be introduced laterally between an IC package and a sidewall of the socket. The damping structures may be attached by adhesive bonding, e.g., to the socket seating plane or IC package, or by press-fit, etc., e.g., in the socket. Damping structures may provide a simple and inexpensive solution tailored for a particular contact, socket, or stack-up having a vibration problem.

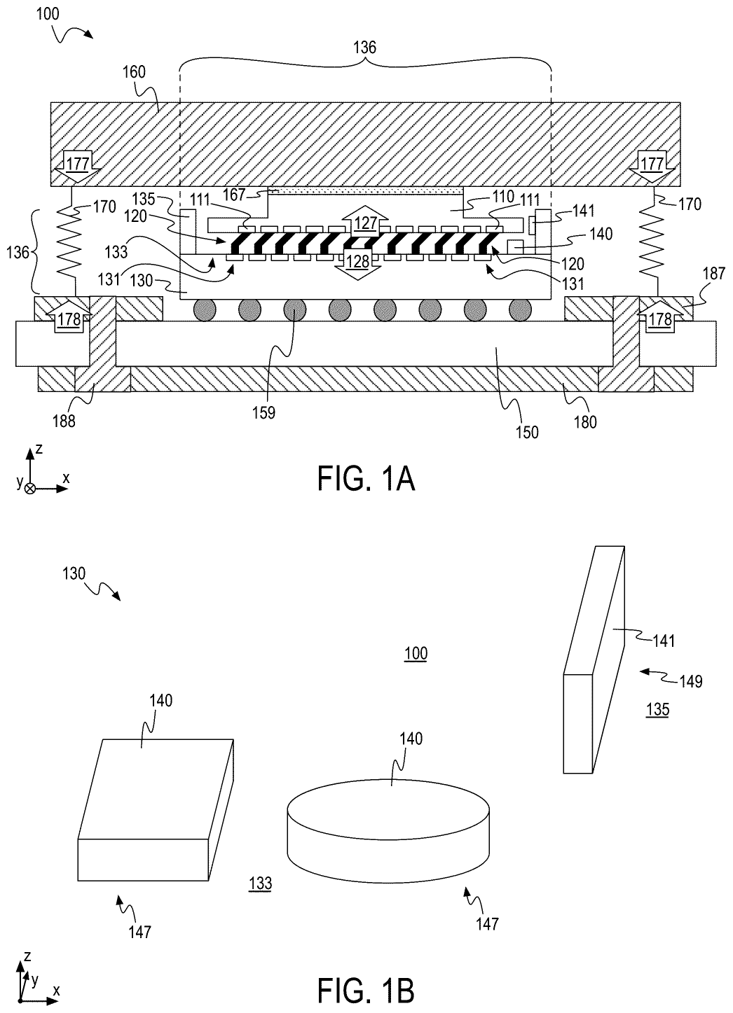

FIGS. 1A and 1B illustrate cross-sectional profile and isometric views of damping structures 140, 141 between an IC package 110 and a socket 130 in an IC device 100, in accordance with some embodiments. FIG. 1A shows a cross-sectional profile view of IC device 100 having IC package 110, socket 130, and damping structures 140, 141 between IC package 110 and socket 130. Socket 130 is coupled to IC package 110 by an array of pins 120 between socket 130 and IC package 110. Damping structures 140, 141 are adjacent to pins 120 and adjacent an edge of the array of pins 120. Damping structures 140, 141 are intervening structures between socket 130 and IC package 110. Seating plane damping structure 140 is between IC package 110 and socket 130 on a horizontal seating plane 133 of socket 130. Sidewall damping structure 141 is between IC package 110 and socket 130 on a vertical sidewall 135 of socket 130. IC package 110 is coupled to a substrate 150 by socket 130. A heatsink 160 is coupled to IC package 110 opposite socket 130.

IC package 110 may include an IC die or dice. Such an IC die may include a piece of silicon or another semiconductor material. Suitable semiconductor substrates include, but are not limited to, single crystal silicon, polycrystalline silicon and silicon on insulator (SOI), as well as similar substrates formed of other semiconductor materials, such a III—V alloy material (e.g., gallium arsenide (GaAs)). Any suitable semiconductor or other material can be used. The substrate may also include semiconductor materials, metals, dielectrics, dopants, and other materials commonly found in semiconductor substrates. IC package 110 may be or include a processor. IC package 110 may include a package substrate on which one or more IC dies may be coupled. IC package 110 may include a package dielectric over the package substrate, e.g., to encapsulate an IC die or dies. In some embodiments, a package substrate includes at least one redistribution layer (RDL). In some embodiments, one or more IC dies are coupled over another IC die or a substrate of similar structure, such as a silicon (or other semiconductor or insulator) interposer.

Socket 130 couples and interfaces with IC package 110. In some embodiments, socket 130 includes pins 120 to contact package lands 111 on (e.g., LGA) package 110. In some embodiments, socket 130 includes socket lands 131 to contact pins 120 on (e.g., PGA) package 110. For example, package lands 111 may be contact pads for pins 120 to touch down on. Socket lands 131 may include contacts that accept package pins 120. Socket 130 may include sidewalls 135, which may accommodate package 110 between them. Sidewalls 135 may form or be part of a periphery 136 of socket 130. Sidewalls 135 may encircle package 110 or help retain package 110 only in certain portions of periphery 136, such as at corners of socket 130. Periphery 136 of socket 130 may extend laterally to the widest portions of socket 130 (e.g., a footprint delineated by sidewalls 135 in the example of FIG. 1A) and extend vertically to the lowest and highest portions of socket 130 (e.g., in the example of FIG. 1A, from the bottom of socket 130, where socket 130 is coupled to substrate 150, to the tops of sidewalls 135). Socket 130 may include a seating plane 133, which may mechanically support package 110 at one or more points between socket 130 and package 110. Socket 130 may include electrical routing, e.g., an interposer or RDL, and may perform a pitch-matching function in coupling the interconnect of IC package 110 with electrical traces of substrate 150. Socket 130 may be of or include any suitable material(s). Some portions of socket 130 may be of an electrically conductive material, such as a metal (e.g., electrical routing, pins 120 or lands 131, etc.), but other materials may be used, such as insulators, for the bulk of socket 130. Socket 130 may include organic materials, such as a hard or strong plastic, e.g., a liquid crystal polymer, for much of socket 130, including seating plane 133. Socket 130 is coupled to substrate 150 by solder bump(s) 159 opposite IC package 110. In some embodiments, socket 130 is otherwise coupled to substrate 150.

Substrate 150 is coupled to socket 130 opposite IC package 110. IC package 110 is coupled to a power supply (not shown) through substrate 150. Substrate 150 may mechanically support and electrically supply IC package 110 and other components (including other substrates or IC packages 110) in an IC system. For example, substrate 150 may be a printed circuit board (PCB), e.g., including electrical traces and one or more thermoset resins (such as bismaleimide triazine (BT) epoxy) and/or a fiberglass weave (as in an FR-4 board, etc.). In some embodiments, substrate 150 is captured by and between back plate 180, bolster plate 187, which are coupled by studs or screws 188.

Heatsink 160 spreads or sinks heat or thermal energy, e.g., away from IC package 110, which may be a processor, etc., that generates large quantities of thermal energy. Heatsink 160 may be or include any suitable structure(s) for dissipating this heat. Such heat dissipation by heatsink 160 may improve the performance and reliability of IC package 110 by limiting a maximum die temperature. Heatsink 160 may include or be coupled to a heat spreader between, and/or in either of, IC package 110 and heatsink 160. For example, a heat spreader may be integrated into IC package 110, e.g., encapsulating the one or more IC dies. Heatsink 160 (and/or a or heat spreader) may be thermally (and otherwise) coupled to package 110 by any suitable means, e.g., affixed or bonded by a thermally conductive material, such as solder or (as in FIG. 1A) other thermal interface material (TIM) 167. Heatsink 160 may include passive or active cooling, e.g., using a coolant fluid, such as in a cold-water block. Some such cooling solutions may be relatively massive and may exert a proportional vertical (e.g., gravitational) force downward on package 110 and socket 130. This force, as well as any other accelerations (besides gravity) on the mass of heatsink 160, may provide significant static load to, and other dynamic implications for, pins 120.

Pins 120 between socket 130 and IC package 110 couple IC package 110 to socket 130 (and substrate 150 and a power supply through socket 130). The array of pins 120 may include hundreds or thousands of pins 120. Pins 120 may be of an elastic material (such as a metal) and compress, e.g., when loaded, which may apply forces 127, 128 between IC package 110 and socket 130. Elastic materials may resist deformation and exert a force proportional to a deformation's magnitude. Pins 120 may be or include compression springs, e.g., flat springs, cantilever springs, etc., which need not be coil or helical springs. Pins 120 may include any suitable material, but may advantageously be sufficiently elastic to contact pads or lands 111 (or pads or lands 131) with acceptable force. Pins 120 may advantageously be sufficiently electrically conductive to make satisfactory electrical contact with pads or lands 111 or 131. In some embodiments, pins 120 include a metal, such as copper. Pins 120 may be part of socket 130 or package 110. In some embodiments, pins 120 are on socket 130 and contact package lands 111 on IC package 110. IC package 110 may sit on seating plane 133 of socket 130 or may extend up from below seating plane 133 in socket 130 to above seating plane 133. In some embodiments, pins 120 are on IC package 110 and contact socket lands 131 on socket 130.

One or more springs 170 are coupled to substrate 150 on one end and heatsink 160 on the other. Spring(s) 170 may provide a high mechanical load as required to seat IC package 110 in socket 130 for maximal electrical contact between pins 120 and lands 111 or 131. Spring(s) 170 may provide forces 177, 178 to retain and to press heatsink 160 to IC package 110 for maximal heat transfer, even when in other physical orientations, e.g., with substrate 150 oriented on its side, as in a server rack. Spring 170 may be a tension or extension spring that applies forces 177, 178, which are transmitted between IC package 110 and socket 130, and balance forces 127, 128 by pulling heatsink 160 and substrate 150 together. Spring 170 need not be a coil spring. In some embodiments, heatsink 160 is rigidly coupled to bolster plate 187. In some embodiments, substrate 150 and back plate 180 are rigidly coupled, and plates 180, 187 are coupled by spring 170 and a spring force. In some embodiments, spring 170 is a compression spring, such as a flat spring or leaf spring. For example, spring 170 may be between plate 187 and one end of screw 188, which may extend through plate 187. In this way, spring 170 may push against the end of screw 188 to press plates 180, 187 together, which may apply a force between package 110 and socket 130 pushing package 110 and socket 130 together. Spring 170 may be of any suitable material(s). Spring 170 may be of an elastic material such that spring 170 pulls or pushes heatsink 160 and substrate 150 together with more force if heatsink 160 and substrate 150 are separated by more than an equilibrium distance. In some embodiments, spring 170 includes a metal, such as spring steel.

IC device 100 may include one or more damping structures 140, 141, as seen in FIGS. 1A and 1B. A damping structure is a structure in, or acting on, an oscillatory or vibrating system that reduces or prevents its oscillation, for example, by dissipating the energy of the oscillation. Damping structures 140, 141 are protruding structures. In the embodiment of FIG. 1A, damping structures 140, 141 protrude from socket 130, which structures 140, 141 are coupled to, and extend towards IC package 110. Damping structures 140, 141 are connected structures, affixed to socket 130 in the embodiment of FIG. 1A. Damping structures 140, 141 are dissipative structures (e.g., of a soft, pliable, or spongy material). Package 110 and socket 130 may be an oscillatory or vibrating system, and damping structures 140, 141 may reduce or minimize vibrations between package 110 and socket 130. Damping structures 140, 141 may reduce the number and/or the magnitude of vibrations by absorbing or dissipating the energy. These vibrations may be oscillations in the relative locations of package 110 and socket 130. Such oscillations may be caused by an initial displacement between package 110 and socket 130, for example, any bump or shock to substrate 150 or heatsink 160 that causes package 110 or socket 130 to move some distance relative to the other. Such a displacement may provide potential energy by stretching or compressing spring 170 (and/or compressing some pins 120). An elastic material of spring 170 (or pins 120) may resist such a displacement and, after elastically storing the potential energy, exert a spring force that acts to reverse the displacement, first to lessen the displacement in the first direction and then to pass back through an equilibrium position to a displacement in a second, opposite direction. The extension of spring 170 (or a pin 120) in the second direction causes the spring element to exert a spring force in the first direction to resist and then reverse the second displacement. The structures, e.g., package 110 and socket 130, may then continue to oscillate back and forth in the first and second directions with the amplitude of the oscillation eventually diminishing to zero as the structures settle into their equilibrium state.

Such vibrations, even if small, may cause damage to package 110. For example, pins 120 on socket 130 may scratch or scrape and cause fretting on package lands 111. Pins 120 on IC package 110 may be damaged by forced exerted by socket lands 131 (e.g., contact holes) where pins 120 meet socket 130. Many small displacements may damage pins 120 or package lands 111 similarly to a single, large displacement. Damping structure 140, 141 may dampen the oscillation, which may reduce the displacement damage. Damping structures 140, 141 may reduce the magnitude of each oscillation cycle and thereby reduce the quantity of oscillation cycles.

Damping structures 140, 141 may dampen oscillations due to their material properties, which may be different than those of a mostly elastic spring. For example, damping structures 140, 141 may resist deformation by virtue of having a significant viscosity and may have a lower elasticity than spring 170 or pins 120. Elastic materials are materials that strain when stretched and immediately return to their original state once the stress is removed. Young's modulus, E, is the modulus of elasticity (in tension or compression) and is the ratio of (tensile/compressive) stress (a force per unit area) and axial strain (proportional deformation) in the elastic region of the material. In an ideal spring of a purely elastic material, a force exerted or experienced by the spring is proportional to the displacement (e.g., compression or extension) from equilibrium as the material of the spring is elastically deformed. This elastic, spring force resists displacement with increasing magnitude as the displacement increases, but also acts to return the spring to its equilibrium position (with decreasing magnitude as the displacement decreases and the spring approaches its equilibrium position). The material of damping structures 140, 141 may have a lower modulus of elasticity (e.g., in pascals (Pa) or GPa) than the material(s) of spring 170 or pins 120. For example, pin 120 or spring 170 may be of an elastic material, such as copper (E>100 GPa) or steel (E˜200 GPa). Even metals with lower elasticities, such as gold or aluminum (both E>50 GPa) may be regarded as fairly elastic. In contrast, damping structures 140, 141 may be of dissipative materials with lower elasticities, such as rubber (E<0.1 GPa) or cork (E<0.02 GPa). The less elastic material of damping structures 140, 141 may result in a lower stiffness (in N/m) than spring 170 or pins 120.

A dissipative material (such as a viscous or viscoelastic material), in contrast to a purely elastic material (as in an ideal spring), is a material that dissipates energy when a load (or displacing force) is applied and then removed. The dissipated energy may be energy converted from kinetic energy to some form of waste energy, such as waste heat or acoustic energy. A viscous or viscoelastic material is more dissipative of kinetic energy than an elastic material. A viscous material (such as a viscoelastic material), as in damping structures 140, 141, resists deformation, but in proportion to the rate of change of the deformation over time (rather than the amount of deformation, e.g., displacement, like an elastic material would). As such, a viscous (or viscoelastic) damping structure 140, 141 may act to lessen the amplitude of one cycle of an oscillation without acting to start the next oscillation cycle. A viscosity may be expressed in pascal-seconds (Pa·s, or MPa·s or GPa·s), and a viscous or viscoelastic material may be an amorphous polymer with a viscosity between 1 MPa-s and 10 GPa·s. In some embodiments, damping structure 140 or 141 is of a viscous or viscoelastic material, and damping structure 140 or 141 is more dissipative of kinetic energy than spring 170 and pins 120. For example, spring 170 and pins 120 may each be of a metal (e.g., spring steel and copper, respectively), and damping structure 140 or 141 may be of rubber. Damping structure 140 or 141 may be of natural or synthetic rubber, such as an elastomer, or of other polymers or amorphous materials. Damping structure 140 or 141 may be of cork or felt.

Damping structures 140, 141 may be located in positions to advantageously dampen oscillations. Notably, damping structures 140, 141 may be deployed within periphery 136 of socket 130, e.g., as delineated by sidewall 135 of socket 130, and adjacent to pins 120. Damping structures 140, 141 may generally reduce vibrations between package 110 and socket 130, but damping structures 140, 141 may be specifically deployed in particularly problematic locations. For example, damping structure 140 is on seating plane 133 and adjacent a problematic pin 120 in particular, e.g., where fretting is observed on a corresponding package land 111. In some embodiments, damping structure 140 or 141 is adjacent an edge of the array of pins 120 where fretting is modeled to be most significant (e.g., where a force in the z direction most significant). In some such embodiments, damping structure 141 is adjacent an edge of the array of pins 120 on sidewall 135, between IC package 110 and sidewall 135.

Damping structures 140, 141 might not bear substantial load at equilibrium and need not affect socket loading design. For example, damping structure 140 may span half a distance between socket 130 (e.g., seating plane 133) and package 110. Damping structure 141 may span half a distance between socket 130 (e.g., sidewall 135) and package 110. In some embodiments, damping structures 140, 141 span more than half the distance between socket 130 and package 110. In other embodiments, damping structures 140, 141 span less than half the distance between socket 130 and package 110. The distance between socket 130 and package 110 may be reduced by loading forces, and damping structures 140, 141 may accept load as loading forces increase (e.g., after a vibration-inducing event). As an example, damping structure 140 may extend up to about 0.25 mm above seating plane 133, pins 120 may extend up to about 0.5 mm above seating plane 133 when not loaded, but pins 120 may compress to about 0.3 mm above seating plane 133 when loaded (e.g., with IC package 110 and springs 170) with about 10 g per pin 120. One or more pins 120 may compress more (or to a lower height), and damping structure 140 may accept load as pins 120 (or at least one pin 120) compress down to about 0.2 mm above seating plane 133 (with the same load of about 10 g per pin 120). In another embodiment, pins 120 may compress to about 0.2 mm above seating plane 133 when further loaded (e.g., to about 20 g per pin 120), and damping structure 140 may accept load. Some heights of pins 120 may be lower or higher than others, or some pins 120 may be compressed more or less, due to non-planarity (e.g., warpage, etc.). Shorter damping structures 140, 141 may prevent interference with the seating of package 110 in socket 130 and/or the contacting of pins 120 to lands 111 or 131. Taller or otherwise larger damping structures 140, 141 may provide more damping. Under vibration load, especially of larger amplitude, damping structures 140, 141 may accept load from pins 120 and reduce oscillations and consequent vibration damage. Damping structure 140 may accept load (or more load) from excessively loaded or compressed pins 120.

In some embodiments, damping structures 140, 141 may be deployed to address an oscillation mode particular to a specific socket 130 (e.g., from a specific vendor) or specific stack-up (e.g., with a specific heatsink 160). For example, damping structure 141 on sidewall 135 may dampen a purely lateral oscillation mode (or at least the lateral component of multidimensional oscillation mode). Damping structure 140 may exert a friction force on a lower surface of package 110 and dampen a lateral oscillation. Different oscillation modes may be caused by various differences between embodiments and may call for different solutions, e.g., materials, shapes, sizes, or locations of damping structures 140, 141. A certain heatsink 160 or corresponding springs 170 may cause an oscillation mode (e.g., rocking back and forth about an axis in an x or y direction, bisecting socket 130) not seen with other heatsinks 160, which may not have as much weight spanning beyond sidewalls 135 of socket 130. A retention or loading solution with more or fewer springs 170, or springs 170 in different locations, may cause an oscillation mode not seen with other solutions. Otherwise similar sockets 130 (but, for example, from different suppliers) may have different oscillation modes due to different pins 120 having different spring characteristics. The ease of deployment and inexpensiveness of materials of damping structures 140, 141 may allow for customizing solutions to vibration issues, e.g., for a particular problem socket 130, for example, after observing troubling fretting, etc.

FIG. 1B illustrates an isometric view of damping structures 140, 141 on socket 130 in IC device 100. Damping structures 140, 141 may be of any suitable size or shape. Sockets 130 and packages 110 may couple tightly together and with small gaps between them, so relatively flat damping structures 140, 141 (e.g., with low aspect ratios) may be advantageous. For example, damping structures 140 may be right rectangular prisms or cylindrical pads of a dissipative, viscous material (as in FIG. 1B) and deployed on seating plane 133 and extending only a short distance up towards package 110. Damping structures 140, 141 may be other shapes, for example, less regular shapes.

Damping structures 140, 141 may be coupled (e.g., fastened) by any suitable structure and/or material. Damping structure 140 may be coupled to socket 130 (at seating plane 133) by an adhesive on a lower surface 147 of damping structure 140. Damping structure 141 may be on sidewall 135 and coupled to socket 130 (at sidewall 135) by an adhesive on a surface 149 of damping structure 141. The adhesive may be a glue, cement, paste, e.g., natural or synthetic, reactive or non-reactive, etc. In some embodiments, the adhesive is an epoxy, other resin, or other polymer-containing substance, including an elastomer. Any suitable adhesive may be utilized.

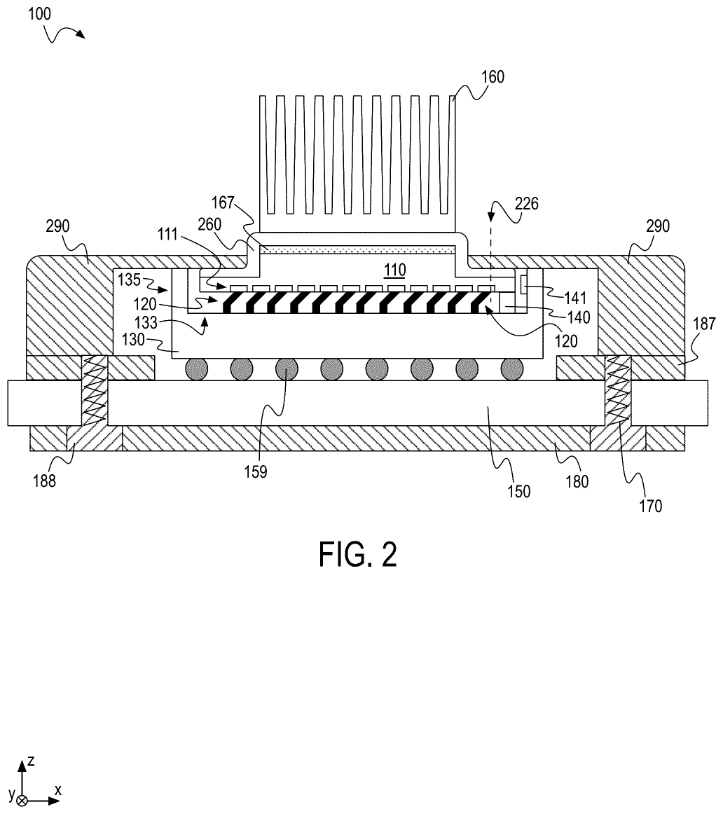

FIG. 2 illustrates a cross-sectional profile view of damping structures 140, 141 between IC package 110 and socket 130 in IC device 100, in accordance with some embodiments. In the embodiment of FIG. 2, socket 130 includes pins 120, which contact package lands 111 on LGA package 110. A heat spreader 260 is coupled to package 110, opposite socket 130 and between package 110 and heatsink 160. Heat spreader 260 directly contacts bracket 290 and heatsink 160.

Heatsink 160 is coupled by heat spreader 260 to package 110 opposite socket 130. Heatsink 160 has fins extending away from a heat-source, e.g., an IC die in package 110. Heatsink 160 may dissipate thermal energy from package 110 up and away from package 110. Fins may thin towards their tips to allow for coolant fluid (e.g., air) flow between fins and over an optimized heat-transfer surface area. A device, such as a fan on substrate 150, may direct a coolant fluid over heatsink 160 and its fins.

IC device 100 may include heat spreader 260 predominantly of a thermally conductive material and having a greater surface area than the heat-generating body to which it is coupled, e.g., an upper surface of an IC die. For example, heat spreader 260 may be or include a metal. Heat spreader 260 may be a structure of copper, a material more thermally conductive than the bulk of IC package 110, e.g., silicon. Heat spreader 260 may be included, e.g., integrated, as part of package 110. Heat spreader 260 may include other materials (e.g., surface finishes, etc.). Advantageously, heat spreader 260 is thin enough to effectively conduct thermal energy from its package (lower) side up, out, and away from IC package 110. Advantageously though, heat spreader 260 is thick enough to effectively conduct thermal energy from its center (e.g., at an IC die) laterally outwards and away from package 110. In some embodiments, heat spreader 260 has a non-uniform thickness (e.g., thick enough to optimize heat conductance away from package 110) and heat transfer area (e.g., thin at its edges). Heat spreader 260 is thermally (and otherwise) coupled to package 110 by TIM 167. Heat spreader 260 may be thermally (and otherwise) coupled to heatsink 160 by any suitable means. In the example of FIG. 2, heatsink 160 is affixed to heat spreader 260 by a thermally conductive solder.

IC package 110 is retained by load plate or bracket 290, which may have a clamshell structure, e.g., attached on one side with a hinge and having an opposite side that can be fastened or undone. In some embodiments, bracket 290 has multiple portions over package 110 and heat spreader 260, for example, a load plate over each side. Bracket 290 may have a latch and/or clasp to close bracket 290 and/or keep package 110 fastened in socket 130 and to substrate 150. Bracket 290 is over socket 130. Bracket 290 may contact heat spreader 260 and may help dissipate thermal energy from IC package 110. Bracket 290 may ensure heat spreader 260 is available (e.g., level and exposed) for contact with heatsink 160 or other structures. Bracket 290 may be coupled to plate 187 rigidly or by a spring force. Spring(s) 170 may couple structures on an upper side of substrate (e.g., plate 187 and/or bracket 290) with plate 180 on a lower side of substrate 150. Provided an initial perturbation, the array of pins 120 (and the associated spring forces) may interact, for example, with a massive heatsink 160, to increase oscillations even without spring(s) 170.

Different stack-ups (e.g., with a different heatsink 160) or retention structures (e.g., with or without a load plate or other bracket 290, and with or without spring(s) 170) may result in different oscillation modes and/or magnitudes without damping structures 140, 141. Different shapes, sizes, quantities, etc., of damping structures 140, 141 may be employed to address, e.g., to tailor a solution to, a particular oscillation encountered.

Multiple damping structures 140, 141 are between IC package 110 and socket 130, and at least one such damping structure 140 is in direct contact with both socket 130 and IC package 110. Damping structure 140 is or includes a pillar of a dissipative material (such as a viscous material, less elastic than the material of spring(s) 170 and pins 120). Damping structure 140 is adjacent an edge 226 of the array of pins 120. A bottom end of this pillar of damping structure 140 is in contact with socket 130, and an upper end of the pillar is in contact with IC package 110. Damping structures 140, 141 directly contacting both package 110 and socket 130 may provide more damping, for example, of oscillations with even imperceptible amplitudes.

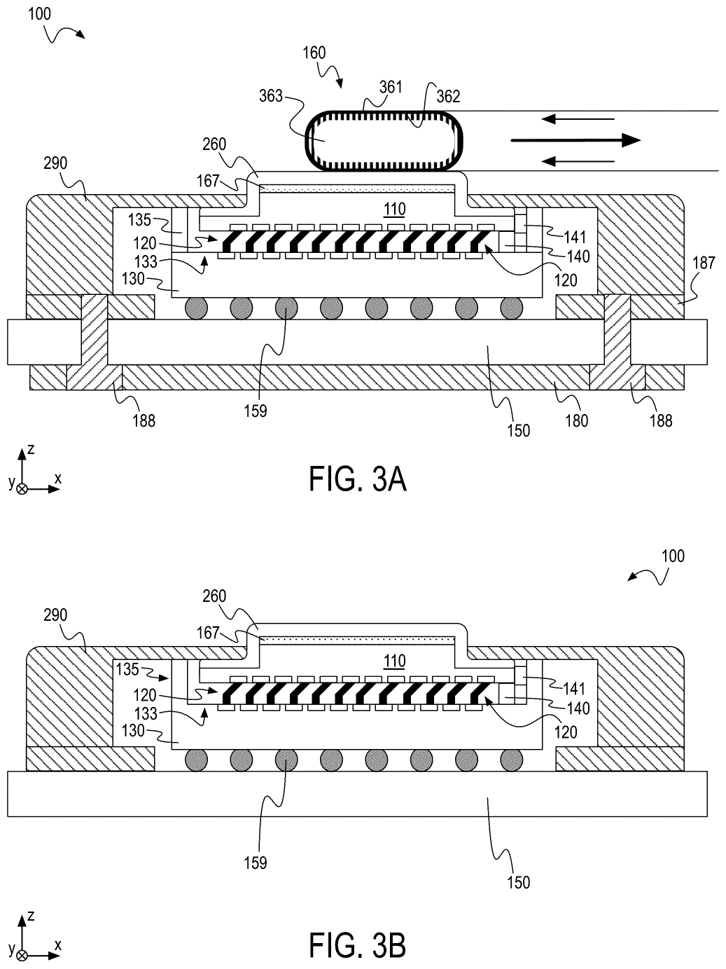

FIGS. 3A and 3B illustrate cross-sectional profile views of damping structures 140, 141 between IC package 110 and socket 130 in IC device 100, in accordance with some embodiments. FIG. 3A shows heat spreader 260 directly contacting bracket 290 and heatsink 160. Bracket 290 is over socket 130, package 110, and heat spreader 260. While no dedicated spring 170 loads pins 120, bracket 290 captures package 110 and applies a loading force to pins 120 when closed. Pins 120 may compress when loaded and apply a force between package 110 and socket 130.

Heat spreader 260 is coupled to heatsink 160, which is notably a heat pipe. TIM 167 is between heat spreader 260 and IC package 110, e.g., over an IC die. Heat pipe heatsink 160 includes an envelope 361, a capillary section or wick 362, and working fluid 363. Heatsink 160 may enhance heat transfer away from IC package 110. Arrows show the direction of travel for working fluid 363 through envelope 361 or wick 362. Working fluid 363 may absorb the heat from IC package 110 at a hot interface (e.g., with heat spreader 260) and vaporize due to the pressure and elevated temperature in envelope 361. Vaporized working fluid 363 may flow through the center of envelope 361 away from the hot interface. Working fluid 363 may condense at a cold interface (not shown) and transfer its latent heat away from IC package 110. The condensed working fluid 363 may return to the hot interface from the cold interface by the capillary section or wick 362. Heat pipe heatsink 160 with larger dimensions may transfer more heat away from IC package 110. Working fluid 363 and the material for envelope 361 may preferentially be chosen for compatibility with each other, e.g., without developing large amounts of non-condensable gas or oxidation products. Material-fluid pairs may be chosen based on temperature operating range. For example, water, methanol, or R134a may be chosen as working fluids 363 compatible with copper envelopes 361. Methanol may be selected for a lower temperature range than water, and R134a may be chosen for a still lower temperature range. Other envelopes 361 or working fluids 363 may be chosen.

Damping structures 140, 141 are both between IC package 110 and socket 130, and both are in direct contact with socket 130 and IC package 110. Damping structures 140, 141 may be on either or both of IC package 110 and socket 130. In some embodiments, damping structures 140, 141 are on and coupled to socket 130. In some embodiments, damping structures 140, 141 are on and coupled to package 110. Damping structures 140, 141 may dampen vibrations, such as those transmitted to IC device 100 through envelope 361 of heatsink 160. The loaded springs of pins 120 may act to sustain oscillations, but damping structures 140, 141 may be deployed to diminish and suppress these oscillations.

FIG. 3B illustrates a similar IC device 100 with damping structures 140, 141 between IC package 110 and socket 130, but without heatsink 160, plate 180, etc. Bracket 290 is over and directly contacts heat spreader 260. Bracket 290 retains package 110 in socket 130, including heat spreader 260 over or integrated with package 110. Damping structures 140, 141 may act to lessen oscillations and minimize vibration damage to pins 120 and/or lands 111 or 131. Vibrations may be initiated by any bump or shock to the system (including substrate 150 and/or any structures substrate 150 is coupled to) or by any other vibration source, such as a fan or other machinery.

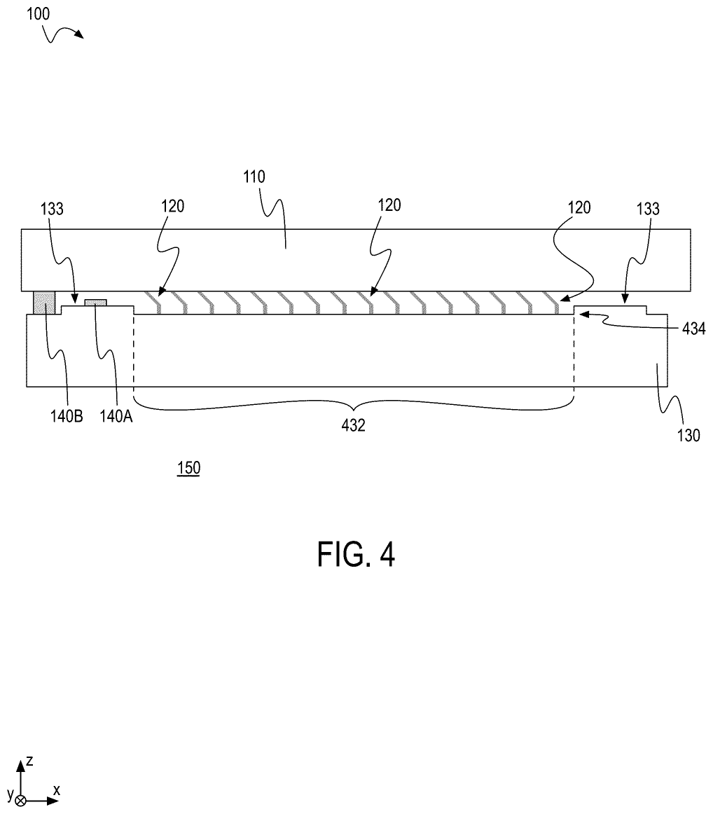

FIG. 4 illustrates a cross-sectional profile view of damping structures 140 between IC package 110 and socket 130 in IC device 100, in accordance with some embodiments. Damping structure 140A is on seating plane 133 and coupled to seating plane 133 (and so socket 130) by an adhesive. Damping structure 140 may be deployed on one or multiple sides of the array of pins 120.

In some embodiments, damping structure 140 extends up from below seating plane 133. For example, as seen in FIG. 4, pins 120 may be in a well 432 of socket 130 and extend up from well plane 434 below seating plane 133, where damping structure 140B is coupled to plane 434 and extends up above seating plane 133. Damping structure 140B may contact package 110 or extend a portion of the distance between socket 130 and package 110. In some embodiments, damping structure 140 extends a portion of the distance between socket 130 and package 110, but contacts package 110 only after pins 120 are loaded and compressed towards socket 130. In some embodiments, damping structures 140 are coupled to socket 130 at multiple levels, e.g., planes 133, 434. In some such embodiments, a taller damping structure 140, for example, on plane 434 further from package 110 or extending up closer to package 110, is of a more pliant or less stiff material. Multiple complementary materials, shapes, or sizes may be deployed together to suppress or diminish oscillations in this way.

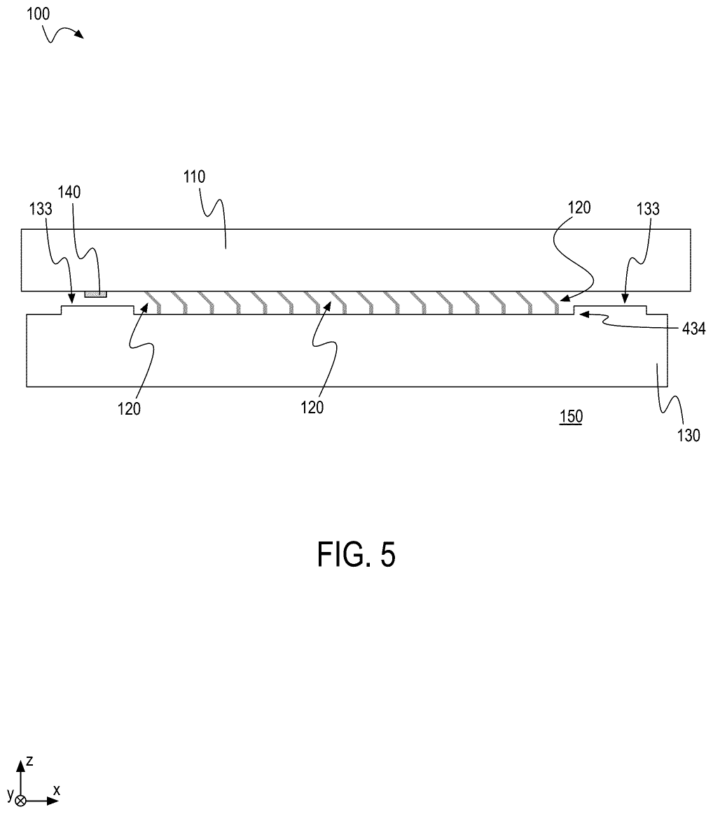

FIG. 5 illustrates a cross-sectional profile view of damping structure 140 between IC package 110 and socket 130 in IC device 100, in accordance with some embodiments. Damping structure 140 is coupled to package 110 by an adhesive. Damping structure 140 may be deployed on one or multiple sides of the array of pins 120. In some embodiments, damping structure 140 and/or an adhesive are more conveniently deployed on package 110 (e.g., on a sufficiently large and flat surface) than on socket 130. In some such embodiments, damping structure 140 is coupled adjacent to an edge of an array of pins 120 on package 110. In some embodiments, damping structure 140 contacts socket 130. In some embodiments, pins 120 are loaded, and damping structure 140 contacts seating plane 133. Damping structure 140 may be located over and contact plane 434.

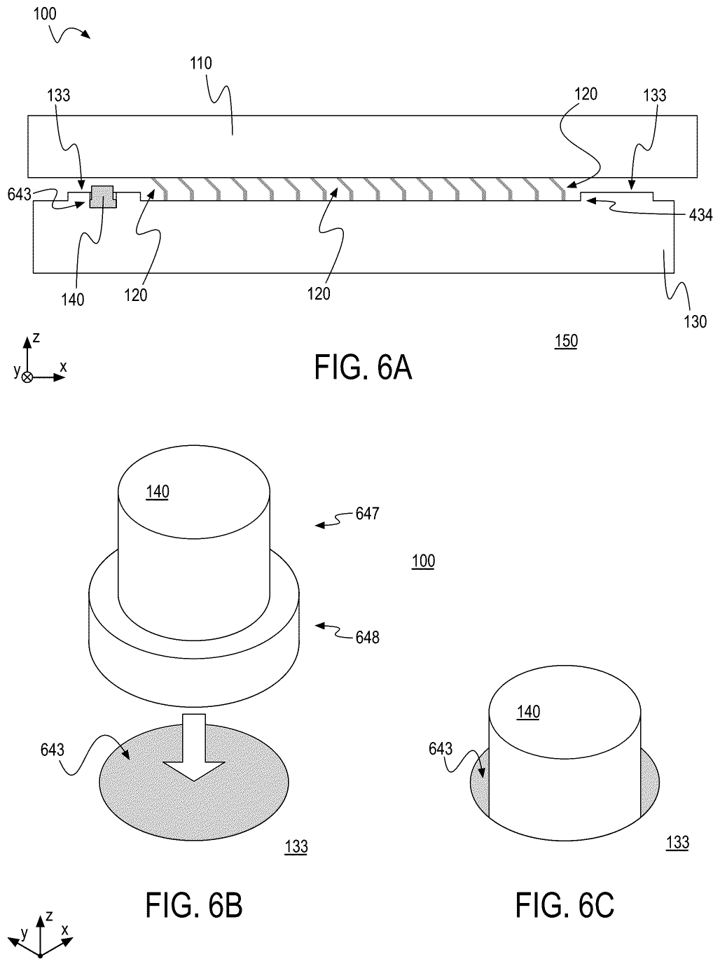

FIGS. 6A, 6B, and 6C illustrate cross-sectional profile and isometric views of damping structure 140 between IC package 110 and socket 130 in IC device 100, in accordance with some embodiments. In the example of FIG. 6A, damping structure 140 is coupled to socket 130 by an interference fit, which may also be referred to as a press (or pressed) fit or a friction fit. Damping structure 140 is located in a hole 643 in seating plane 133 and extends up from below seating plane 133. In some embodiments, as in FIGS. 6A-6C, damping structure 140 has multiple diameters or thicknesses, which assists in inserting or retaining damping structure 140 in hole 643. In other embodiments, damping structure 140 has a single diameter or thickness, and damping structure 140 is otherwise retained, e.g., by friction.

FIGS. 6B and 6C show damping structure 140 and hole 643 in seating plane 133. Damping structure 140 has an upper portion 647 with a narrower, top diameter and a lower portion 648 (e.g., a flange) with a wider, bottom diameter. At seating plane 133, hole 643 has a diameter wider than the top diameter of upper portion 647 and narrower than the bottom diameter of lower portion 648. Hole 643 may have a narrower or wider diameter below seating plane 133. The narrower hole 643 retains damping structure 140 by interfering or obstructing the wider, bottom portion 648 (e.g., with friction) from passing through hole 643. In some embodiments, damping structure 140 is of a sufficiently flexible material (and/or the diameters of hole 643 and the wider, bottom portion 648 are matched closely enough) to allow insertion of damping structure 140 into hole 643. Upper portion 647 of damping structure 140 extends towards package 110, out of hole 643, and above seating plane 133.

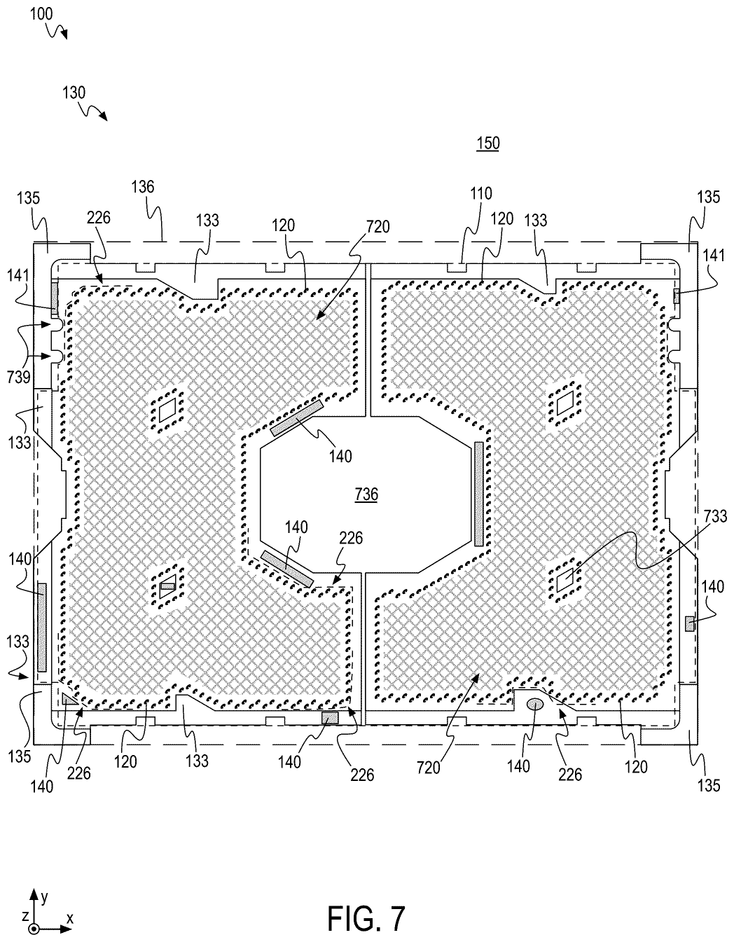

FIG. 7 illustrates a plan view of damping structures 140, 141 between IC package 110 and socket 130 in IC device 100, in accordance with some embodiments. Socket 130 is shown as if seeing through package 110. Package 110 is shown by short dashes representing an edge of package 110 inside socket 130, periphery 136 of which is shown by longer dashes, for example, along an outer surface of sidewalls 135. Periphery 136 overlaps and is coterminous with a footprint of socket 130 at least at some locations. Pins 120 are shown encircling fields 720 (represented by crosshatching) within socket 130. Fields 720 may be filled with an array of pins 120. Though not shown, IC device 100 may include bracket 290 and/or one or more springs 170, for example, to load pins 120. Socket 130 and sidewall 135 may have keying or alignment features 739, which may ensure that only a complementary package 110 is coupled with socket 130 and that package 110 is properly aligned before seating in socket 130 and loading pins 120.

Multiple damping structures 140, 141 are shown on socket 130. The locations of damping structures 140, 141 are possible examples for deployment. Some or all of the locations, as well as other locations, may be used for damping structures 140, 141. Some locations may be better suited for addressing certain oscillation modes. Some modes may affect multiple regions of the array of pins 120 substantially equally, but some modes may impact certain regions more than others. For example, a rocking mode may be about an axis, e.g., in the vertical or y direction and between loading structures above and below socket 130. Such a mode may have larger vertical displacements and exert greater vertical forces at both sides (at extremes in the x directions) and might best be mitigated by damping structures 140 there, where vertical forces are greatest.

Damping structures 140, 141 are within periphery 136 of socket 130. Damping structures 140, 141 are between socket 130 and package 110. For example, damping structures 140 are vertically between socket 130 and package 110. In some such embodiments, damping structures 140 are on and coupled to seating plane 133 and under package 110. In other embodiments, damping structures 140 are on and coupled to an underside of package 110. For example, some sockets 130 may have a well 736, which may allow for mounting components on substrate 150 or on an underside of package 110. Coupling one or more damping structures 140 to an underside of package 110 may be more convenient than on seating plane 133, as package 110 may be more suitable (e.g., having a greater or flatter surface for applying an adhesive). Damping structures 140 vertically between socket 130 and package 110 may directly contact one or both of socket 130 and package 110. In some embodiments, damping structures 140 vertically between package 110 and socket 130 are coupled to seating plane 133 at an interstitial seating plane 733, which may be portions of seating plane 133 within field 720 of pins 120. In some embodiments, damping structure 140 is coupled to an underside of package 110 and contacts interstitial seating plane 733 during vibrations. In some such embodiments, damping structure 140 also contacts interstitial seating plane 733 under static load.

Damping structures 140 may be coupled by either or both of an adhesive or an interference fit. At least some damping structures 140, 141 are adjacent edge 226 of the array of pins 120. Some portions of edge 226 are illustrated with a dashed line. Some damping structures 140, 141 are adjacent two edges of the array of pins 120, e.g., at a corner of socket 130 and the array of pins 120. Some damping structures 140, 141 are between pins 120 and sidewall 135 of socket 130.

Damping structures 141 are between sidewall 135 and package 110. In the example of FIG. 7, damping structures 141 are in direct contact with each of socket 130 and IC package 110. In some embodiments, damping structures 141 contact only one of socket 130 and IC package 110. In some embodiments, damping structure 141 is coupled to IC package 110 by an adhesive. In some embodiments, damping structure 141 is coupled to socket 130 (and sidewall 135) by an adhesive.

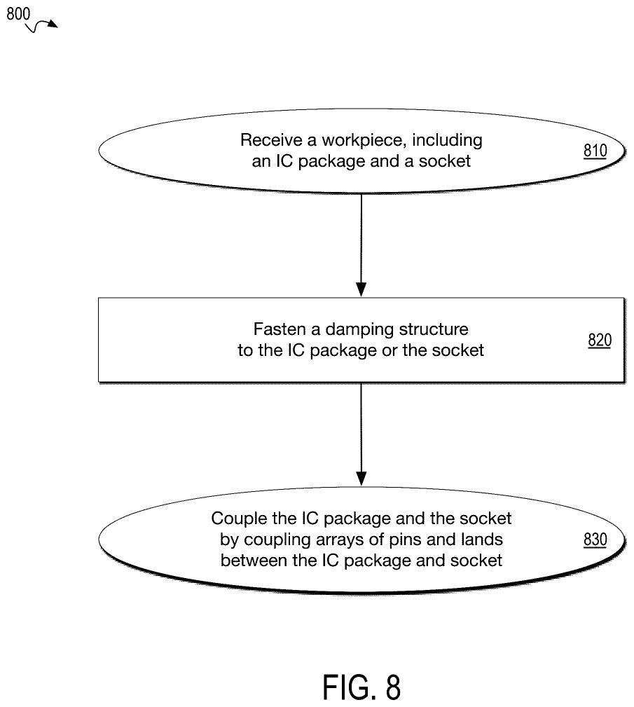

FIG. 8 is a flow chart of methods 800 for forming an IC device with an IC package, a socket, and a damping structure between the package and socket, in accordance with some embodiments. Methods 800 include operations 810-830. Additional operations may be included. FIG. 8 shows an example sequence, but the operations can be done in other orders as well, and some operations may be omitted. Some operations can also be performed multiple times before other operations are performed. For example, multiple damping structures may be fastened to the package and/or socket. Some operations may be included within other operations so that the number of operations illustrated FIG. 8 is not a limitation of the methods 800.

At operation 810, a workpiece is received. The workpiece may include multiple parts or portions, which may be together (e.g., coupled) or separate. For example, the workpiece may include an IC package and a socket, and these and other workpiece portions may be much as described at FIG. 1A, etc. Likewise, the descriptions of methods 800 may describe the structures, etc., of FIGS. 1A-7. The IC package may include one or more IC dies, which may be on a package substrate. Such a package substrate may include electrical lines (e.g., traces, vias, etc.), for example, to perform as an interposer or RDL. A package substrate may also have interconnect interfaces for coupling an IC die (or dice) to a socket. The socket may be electrically and mechanically complementary to the IC package, e.g., by having pins or lands that correspond to lands or pins on the package. For example, the socket may have an array of pins to contact an LGA on the package, or may have lands (e.g., contact slots) for mating with an array of pins on the package. The socket may be on a system substrate (such as a PCB, e.g., a motherboard) and may electrically couple the IC package to the system substrate much as a package substrate may interconnect or interface (e.g., with electrical lines) between one or more IC dies and the socket. The socket may be soldered or otherwise attached to such a system substrate. Other structures or materials may be received, either coupled to or separate from the portions already described. In some embodiments, a heat spreader and/or heatsink is received. In some embodiments, one or more of a load plate or bracket or loading springs are received.

A damping structure is fastened to the IC package or the socket at operation 820. The damping structure may be of or include a dissipative material, such as a viscoelastic material, that may act to diminish vibrations between the IC package and the socket. In some embodiments, the viscoelastic material is less elastic or more viscous (and more dissipative of kinetic energy) than the elastic material of the pins (of the socket or package) or a spring for loading the pins. The dissipative or viscoelastic material may be cork or felt or an amorphous polymer-containing material, such as a rubber or rubber-like material. The dissipative or viscoelastic material may be natural or synthetic. In some embodiments, the dissipative or viscoelastic material is an elastomer.

The damping structure may be a pillar of the dissipative or viscoelastic material that extends vertically between the IC package and the socket. Such a pillar may be fastened to, and extend up from, a seating plane of the socket. A damping pillar may extend up from below the seating plane, e.g., from a hole or well in the seating plane. The damping structure may be fastened to the package, for example, to a surface with pins or lands, but outside the array of pins or lands or in a gap between the pins or lands. A pillar of dissipative or viscoelastic material need not extend vertically from the IC package or the socket. The damping structure may be between, and attached to one of, a sidewall of the socket and a side of the IC package. Likewise, the term “pillar” does not imply a shape or aspect ratio of the damping structure; a damping pillar may be relatively short or flat, and a pillar may have an irregular shape. For example, a dissipative pillar may be a long, broad pad protruding up only a portion of the short distance between the IC package and the socket, but along a significant portion of a side or edge of an array of pins. A damping structure may have a non-pillar shape as well. In some embodiments, a damping structure is a pad with one or more holes or openings, e.g., for one or more pins to pass through to contact a land.

The damping structure may be fastened using any suitable means or materials. In some embodiments, the damping structure is fastened using an adhesive, such as a glue, cement, or paste. The adhesive may be an epoxy, other resin, or other polymer-containing substance, including an elastomer. In some embodiments, the adhesive is applied to the socket or the IC package, and the damping structure is placed on the socket or package at the adhesive. In other embodiments, the adhesive is applied to the damping structure, and the damping structure is placed on the socket or package where desired. In some embodiments, the adhesive is applied to both the damping structure and one of the socket and the IC package. Application of the adhesive may be by brush, positive displacement (e.g., squeeze tube), or any other satisfactory method. Any suitable adhesive may be utilized, e.g., natural or synthetic, reactive or non-reactive, etc., and in any suitable fashion.

The damping structure may be fastened using a press or interference fit. For example, a flexible damping structure (such as an elastomer pillar) may be pressed into a hole or cavity, e.g., in the socket, and held in place by friction or obstruction. In some embodiments, the damping structure has a flange, ridge, etc., that is wider than the hole, but that is forced into or through the hole and may elastically deform to form a tight-fitting joint. In some embodiments, the damping structure (with or without a flange) is cooled such that the dissipative or viscoelastic material contracts sufficiently to fit in the cavity before warming and expanding to form the press or interference fit. Other means may be employed, such as snap fit (annular or otherwise), screwing a damping structure into a threaded hole, etc.

The damping structure may be fastened in any suitable location and orientation, e.g., in a location between the IC package and the socket. Such a location may be within a periphery of the socket on either or both of the IC package and socket. A damping structure may act to diminish vibration damage generally, but a damping structure may be utilized locally to address an observed or modeled issue with a particular pairing of package and socket. For example, a damping structure may be located immediately adjacent to a pin or land where damage is observed. Such damage may be fretting on a contact pad or plastic deformation of a pin, and a damping structure may be deployed as close as is feasible to the pad or pin where damage is observed (or on the opposing surface). A damping structure may also be employed preemptively, e.g., using modeling of the forces exerted on and by pins in a socket given certain loading structures. The greatest forces modeled or damage(s) observed may be at or near an edge of the array of pins or lands. A damping structure may be fastened to the IC package or the socket adjacent the edge of the array of pins or lands, on either the structure (package or socket) where the damage is observed (or modeled to be likely) or on the opposite surface. In some embodiments, the damping structure is fastened at a corner of the array of pins or lands, e.g., at a meeting of two edges of the array. A damping structure may be effective in diminishing vibrations even when located away from the (observed or modeled) region of concern, and a damping structure may be placed where convenient. In some embodiments, a damping structure is fastened to an interstitial seating plane, e.g., on a pedestal within an array of pins, in a socket well.

At operation 830, the IC package and the socket are coupled. The coupling may include contacting pins on a socket to lands on a package, or vice versa. An array of contact pads on a package, e.g., an LGA on an LGA package substrate, may be aligned and brought together with a corresponding array of pins in an LGA socket. Likewise, an array of pins on a package may be aligned and brought together with a corresponding array of lands (e.g., pin slots) in a complementary socket. The package and socket may be coupled with the damping structure between the package and socket. While the pins and lands may be vertically between the package and socket, the damping structure may be laterally between the package and socket, e.g., on a sidewall of the socket.

The IC package and the socket may be aligned prior to contacting the pins and lands. A matched pair of socket and package may have corresponding keying or alignment features to assist with aligning (and to ensure non-matched pairs are not coupled). For example, a protrusion on a socket sidewall may fit into a corresponding cutout in a matched IC package substrate. Unmatched packages and sockets may have protrusions and cutouts, but in non-corresponding locations.

The IC package and the socket may be loaded or otherwise retained after contacting the pins and lands. Loading may include applying a force to ensure proper contact between the pins and lands. Such a force may include the weight of a massive heatsink. A loading force may be applied by one or more springs acting to pull the package and socket together, e.g., coupling a heatsink above the package to a substrate below the socket. A loading force may be applied by a load plate or bracket over the package, which may retain the package in the socket. A load plate or bracket may include a clasp or latch to keep retention solution closed when desired. A latch may be used to close the load plate or bracket, for example, after ensuring the package and socket are properly aligned. Loading the pins between package and socket may compress the pins and bring the package and socket closer together. In some embodiments, a damping structure is on one of the package or socket, and the damping structure is brought into contact with the other of the package and socket when the pins are loaded. In other embodiments, the damping structure contacts only one of the package and socket, even after the pins are loaded.

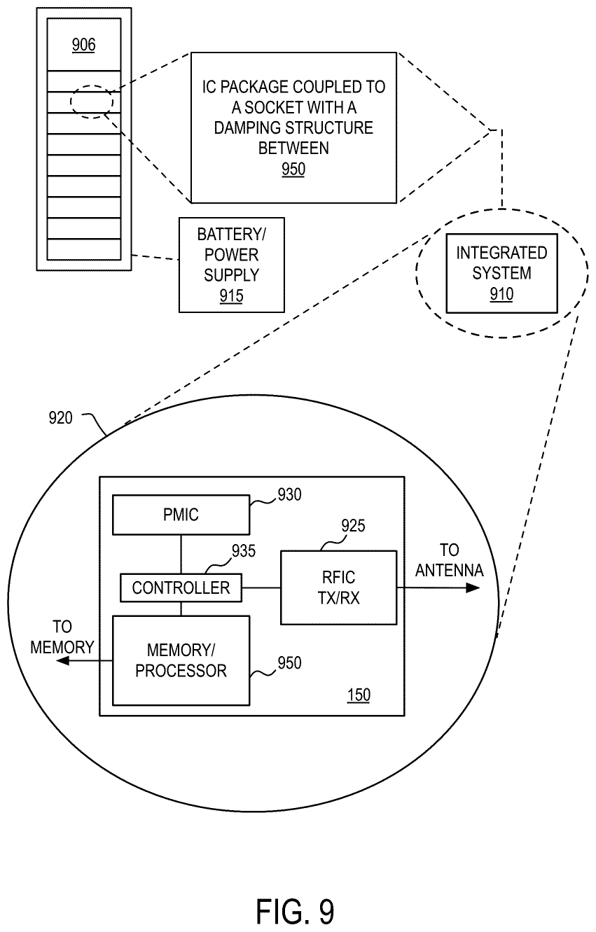

FIG. 9 illustrates a diagram of an example data server machine 906 employing an IC package in a socket with a damping structure between the package and socket, in accordance with some embodiments. Server machine 906 may be any commercial server, for example, including any number of high-performance computing platforms disposed within a rack and networked together for electronic data processing, which in the exemplary embodiment includes one or more devices 950 having a damping structure between an IC package and socket.

Also as shown, server machine 906 includes a battery and/or power supply 915 to provide power to devices 950, and to provide, in some embodiments, power delivery functions such as power regulation. Devices 950 may be deployed as part of a package-level integrated system 910. Integrated system 910 is further illustrated in the expanded view 920. In the exemplary embodiment, devices 950 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 950 is a microprocessor including a static RAM (SRAM) cache memory. As shown, device 950 may be an IC device with a damping structure between an IC package and socket, as discussed herein. Device 950 may be further coupled to (e.g., communicatively coupled to) a board, an interposer, or a system substrate 150 along with, one or more of a power management IC (PMIC) 930, RF (wireless) IC (RFIC) 925 including a wideband RF (wireless) transmitter and/or receiver (TX/RX) (e.g., including a digital baseband and an analog front end module further includes a power amplifier on a transmit path and a low noise amplifier on a receive path), and a controller 935 thereof. In some embodiments, RFIC 925, PMIC 930, controller 935, and device 950 include damping structure between an IC package and socket.

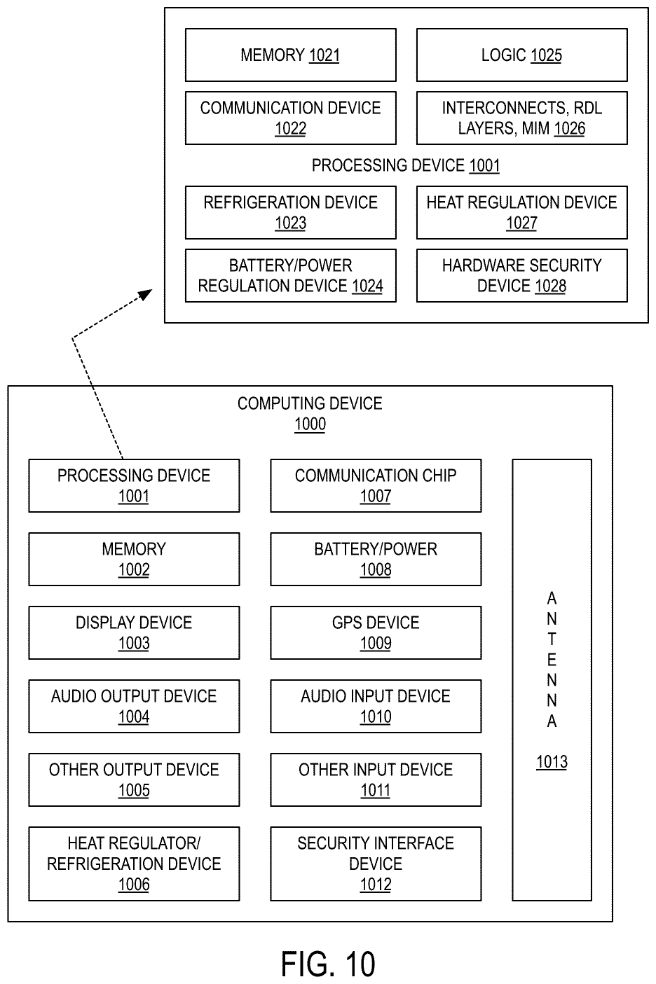

FIG. 10 is a block diagram of an example computing device 1000, in accordance with some embodiments. For example, one or more components of computing device 1000 may include any of the devices or structures discussed herein. A number of components are illustrated in FIG. 10 as being included in computing device 1000, but any one or more of these components may be omitted or duplicated, as suitable for the application. In some embodiments, some or all of the components included in computing device 1000 may be attached to one or more printed circuit boards (e.g., a motherboard). In some embodiments, various ones of these components may be fabricated onto a single system-on-a-chip (SoC) die. Additionally, in various embodiments, computing device 1000 may not include one or more of the components illustrated in FIG. 10, but computing device 1000 may include interface circuitry for coupling to the one or more components. For example, computing device 1000 may not include a display device 1003, but may include display device interface circuitry (e.g., a connector and driver circuitry) to which display device 1003 may be coupled. In another set of examples, computing device 1000 may not include an audio output device 1004, other output device 1005, global positioning system (GPS) device 1009, audio input device 1010, or other input device 1011, but may include audio output device interface circuitry, other output device interface circuitry, GPS device interface circuitry, audio input device interface circuitry, audio input device interface circuitry, to which audio output device 1004, other output device 1005, GPS device 1009, audio input device 1010, or other input device 1011 may be coupled.

Computing device 1000 may include a processing device 1001 (e.g., one or more processing devices). As used herein, the term “processing device” or “processor” indicates a device that processes electronic data from registers and/or memory to transform that electronic data into other electronic data that may be stored in registers and/or memory. Processing device 1001 may include a memory 1021, a communication device 1022, a refrigeration device 1023, a battery/power regulation device 1024, logic 1025, interconnects 1026 (i.e., optionally including redistribution layers (RDL) or metal-insulator-metal (MIM) devices), a heat regulation device 1027, and a hardware security device 1028.

Processing device 1001 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 1000 may include a memory 1002, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 1002 includes memory that shares a die with processing device 1001. This memory may be used as cache memory and may include embedded dynamic random-access memory (eDRAM) or spin transfer torque magnetic random-access memory (STT-MRAM).

Computing device 1000 may include a heat regulation/refrigeration device 1006. Heat regulation/refrigeration device 1006 may maintain processing device 1001 (and/or other components of computing device 1000) at a predetermined low temperature during operation.

In some embodiments, computing device 1000 may include a communication chip 1007 (e.g., one or more communication chips). For example, the communication chip 1007 may be configured for managing wireless communications for the transfer of data to and from computing device 1000. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 1007 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1007 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1007 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1007 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1007 may operate in accordance with other wireless protocols in other embodiments. Computing device 1000 may include an antenna 1013 to facilitate wireless communications and/or to receive other wireless communications (such as AM or FM radio transmissions).

In some embodiments, communication chip 1007 may manage wired communications, such as electrical, optical, or any other suitable communication protocols (e.g., the Ethernet). As noted above, communication chip 1007 may include multiple communication chips. For instance, a first communication chip 1007 may be dedicated to shorter-range wireless communications such as Wi-Fi or Bluetooth, and a second communication chip 1007 may be dedicated to longer-range wireless communications such as GPS, EDGE, GPRS, CDMA, WiMAX, LTE, EV-DO, or others. In some embodiments, a first communication chip 1007 may be dedicated to wireless communications, and a second communication chip 1007 may be dedicated to wired communications.

Computing device 1000 may include battery/power circuitry 1008. Battery/power circuitry 1008 may include one or more energy storage devices (e.g., batteries or capacitors) and/or circuitry for coupling components of computing device 1000 to an energy source separate from computing device 1000 (e.g., AC line power).

Computing device 1000 may include a display device 1003 (or corresponding interface circuitry, as discussed above). Display device 1003 may include any visual indicators, such as a heads-up display, a computer monitor, a projector, a touchscreen display, a liquid crystal display (LCD), a light-emitting diode display, or a flat panel display, for example.

Computing device 1000 may include an audio output device 1004 (or corresponding interface circuitry, as discussed above). Audio output device 1004 may include any device that generates an audible indicator, such as speakers, headsets, or earbuds, for example.

Computing device 1000 may include an audio input device 1010 (or corresponding interface circuitry, as discussed above). Audio input device 1010 may include any device that generates a signal representative of a sound, such as microphones, microphone arrays, or digital instruments (e.g., instruments having a musical instrument digital interface (MIDI) output).

Computing device 1000 may include a GPS device 1009 (or corresponding interface circuitry, as discussed above). GPS device 1009 may be in communication with a satellite-based system and may receive a location of computing device 1000, as known in the art.

Computing device 1000 may include other output device 1005 (or corresponding interface circuitry, as discussed above). Examples of the other output device 1005 may include an audio codec, a video codec, a printer, a wired or wireless transmitter for providing information to other devices, or an additional storage device.

Computing device 1000 may include other input device 1011 (or corresponding interface circuitry, as discussed above). Examples of the other input device 1011 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1000 may include a security interface device 1012. Security interface device 1012 may include any device that provides security measures for computing device 1000 such as intrusion detection, biometric validation, security encode or decode, access list management, malware detection, or spyware detection.

Computing device 1000, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1A-10. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an apparatus includes an integrated circuit (IC) package, a socket coupled to the IC package by a plurality of pins therebetween and a spring to apply a force between the IC package and the socket, and a damping structure between the IC package and the socket and adjacent to the pins, wherein the damping structure is more dissipative of kinetic energy than the spring.

In one or more second embodiments, further to the first embodiments, the apparatus also includes a plurality of damping structures, at least one of which is in direct contact with each of the socket and the IC package.

In one or more third embodiments, further to the first or second embodiments, the damping structure is within a periphery of the socket.

In one or more fourth embodiments, further to the first through third embodiments, the damping structure is adjacent an edge of the plurality of pins.

In one or more fifth embodiments, further to the first through fourth embodiments, the damping structure is between the IC package and a sidewall of the socket.

In one or more sixth embodiments, further to the first through fifth embodiments, the socket includes the plurality of pins, and the IC package includes a land grid array (LGA).

In one or more seventh embodiments, further to the first through sixth embodiments, the damping structure is coupled to the IC package or the socket by an adhesive or an interference fit.

In one or more eighth embodiments, further to the first through seventh embodiments, the spring includes a first material, the damping structure includes a second material, different than the first material, and the socket includes a third material, different than the first and second materials.

In one or more ninth embodiments, further to the first through eighth embodiments, the damping structure includes a pillar of the second material, a first end of the pillar in contact with the IC package and a second, opposite end of the pillar in contact with the socket.

In one or more tenth embodiments, further to the first through ninth embodiments, the first material has an elasticity greater than an elasticity of the second material.

In one or more eleventh embodiments, further to the first through tenth embodiments, the apparatus also includes a substrate coupled to the socket distal the IC package, and the spring is coupled to the substrate.

In one or more twelfth embodiments, further to the first through eleventh embodiments, the apparatus also includes a heatsink or a heat spreader coupled to the IC package distal the socket.

In one or more thirteenth embodiments, an apparatus includes a substrate, a socket coupled to the substrate, an integrated circuit (IC) package coupled to the substrate by the socket and a spring to apply a force between the IC package and the socket, wherein a plurality of pins on a first of the socket or the IC package are in contact with a plurality of lands on a second of the socket or the IC package, and a damping structure between, and in contact with at least one of, the IC package and the socket, wherein the damping structure includes a viscous material.

In one or more fourteenth embodiments, further to the thirteenth embodiments, the damping structure is within a periphery of the socket.

In one or more fifteenth embodiments, further to the thirteenth or fourteenth embodiments, the spring is coupled to the substrate.

In one or more sixteenth embodiments, further to the thirteenth through fifteenth embodiments, the damping structure is coupled to the socket by an adhesive or an interference fit.

In one or more seventeenth embodiments, further to the thirteenth through sixteenth embodiments, the IC package is coupled to a power supply through the substrate.

In one or more eighteenth embodiments, a method includes receiving a workpiece including an integrated circuit (IC) package and a socket, fastening a damping structure to the IC package or the socket, the damping structure including a dissipative material, and coupling the IC package and the socket, wherein a first of the IC package and the socket includes an array of pins, a second of the IC package and the socket includes an array of lands, and coupling the IC package and the socket includes contacting the array of pins to the array of lands with the damping structure between the IC package and the socket.

In one or more nineteenth embodiments, further to the eighteenth embodiments, fastening the damping structure includes fastening the damping structure adjacent an edge of the array of pins or the array of lands.

In one or more twentieth embodiments, further to the eighteenth or nineteenth embodiments, fastening the damping structure includes fastening the damping structure on a seating plane of the socket.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An apparatus, comprising:
an integrated circuit (IC) package;
a socket coupled to the IC package by a plurality of pins therebetween and a spring; and
a protruding structure between the IC package and the socket and adjacent to the pins, wherein the protruding structure comprises a polymeric material.

2. The apparatus of claim 1, further comprising a plurality of protruding structures, at least one of which is in direct contact with each of the socket and the IC package.

3. The apparatus of claim 1, wherein the protruding structure is within a periphery of the socket.

4. The apparatus of claim 1, wherein the protruding structure is adjacent an edge of the plurality of pins.

5. The apparatus of claim 1, wherein the protruding structure is between the IC package and a sidewall of the socket.

6. The apparatus of claim 1, wherein the socket includes the plurality of pins, and the IC package includes a land grid array (LGA).

7. The apparatus of claim 1, wherein the protruding structure is coupled to the IC package or the socket by an adhesive or an interference fit.

8. The apparatus of claim 1, wherein the spring comprises a first material, the protruding structure comprises a second material, different than the first material, and the socket comprises a third material, different than the first and second materials.

9. The apparatus of claim 8, wherein the protruding structure comprises a pillar of the second material, a first end of the pillar in contact with the IC package and a second, opposite end of the pillar in contact with the socket.

10. The apparatus of claim 8, wherein the first material has an elasticity greater than an elasticity of the second material.

11. The apparatus of claim 1, further comprising a substrate coupled to the socket distal the IC package, wherein the spring is coupled to the substrate.

12. The apparatus of claim 1, further comprising a heatsink or a heat spreader coupled to the IC package distal the socket.

13. An apparatus, comprising:
a substrate;
a socket coupled to the substrate;
an integrated circuit (IC) package coupled to the substrate by the socket and a spring to apply a force between the IC package and the socket, wherein a plurality of pins on a first of the socket or the IC package are in contact with a plurality of lands on a second of the socket or the IC package; and
a damping structure between, and in contact with at least one of, the IC package and the socket, wherein the damping structure comprises a dissipative or viscoelastic material.

14. The apparatus of claim 13, wherein the damping structure is within a periphery of the socket.

15. The apparatus of claim 14, wherein the spring is coupled to the substrate.

16. The apparatus of claim 15, wherein the damping structure is coupled to the socket by an adhesive or an interference fit.

17. The apparatus of claim 16, wherein the IC package is coupled to a power supply through the substrate.

18. A method, comprising:
receiving a workpiece comprising an integrated circuit (IC) package and a socket;
fastening a damping structure to the IC package or the socket, the damping structure comprising a dissipative material; and
coupling the IC package and the socket, wherein a first of the IC package and the socket comprises an array of pins, a second of the IC package and the socket comprises an array of lands, and coupling the IC package and the socket comprises contacting the array of pins to the array of lands with the damping structure between the IC package and the socket.

19. The method of claim 18, wherein fastening the damping structure comprises fastening the damping structure adjacent an edge of the array of pins or the array of lands.

20. The method of claim 18, wherein fastening the damping structure comprises fastening the damping structure on a seating plane of the socket.
